(19) United States
(12) Patent Application Publication
(10) Pub. No.: US 2025/0336811 A1
(43) Pub. Date: Oct. 30, 2025

(54) HIGH-PRECISION BACKSIDE RESISTOR

(71) Applicant: QUALCOMM Incorporated, San Diego, CA (US)

(72) Inventors: John Jianhong ZHU, San Diego, CA (US); Junjing BAO, San Diego, CA (US); Abhishek JAIN, San Diego, CA (US); Giridhar NALLAPATI, San Diego, CA (US)

(21) Appl. No.: 18/645,089

(22) Filed: Apr. 24, 2024

(51) Int. Cl. H01L 23/522

(52) U.S. Cl. CPC H01L 23/5228; H10D 1/474

(57) ABSTRACT

A high-precision backside resistor and method for making the same are disclosed. In an aspect, a backside resistor structure disposed between a frontside level-zero metal (FM0) layer and a backside level-zero metal (BM0) layer comprises a first terminal electrically coupled to a first frontside structure through a first conductive path comprising at least a first backside contact (BSC), and a second terminal electrically coupled to a second frontside structure through a second conductive path comprising at least a second BSC.

### BACKGROUND OF THE DISCLOSURE

### 1. Field of the Disclosure

This disclosure relates generally to semiconductor wafer process, and more specifically to high-precision backside resistors and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device, where the “frontside” originally referred to the side having electrical contacts to other devices and the “backside” originally referred to the surface of the substrate opposite the surface upon which the components were fabricated, i.e., the backside of the substrate. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor apparatus includes a backside resistor structure having a first terminal and a second terminal and being disposed between a frontside level-zero metal (FM0) layer and a backside level-zero metal (BM0) layer, wherein the first terminal is electrically coupled to a first frontside structure through a first conductive path comprising at least a first backside contact (BSC), wherein the second terminal is electrically coupled to a second frontside structure through a second conductive path comprising at least a second BSC, and wherein at least one of the first frontside structure or the second frontside structure comprises a frontside contact, a frontside epitaxial structure, or a frontside gate structure.

In an aspect, a semiconductor apparatus includes a backside resistor structure having a first terminal and a second terminal and being disposed between a first backside metal layer and a second backside metal layer, wherein the first terminal is electrically coupled to a first frontside structure through a first conductive path comprising at least a first BSC, first backside level-zero via (BSV0), a first BM0 structure, and a first backside level-one via (BSV1), wherein the second terminal is electrically coupled to a second frontside structure through a second conductive path comprising at least a second BSC, a second BSV0, a second BM0 structure, and a second BSV1, and wherein at least one of the first frontside structure or the second frontside structure comprises a frontside contact, a frontside epitaxial structure, or a frontside gate structure.

In an aspect, a method for fabricating a semiconductor apparatus includes providing a substrate having a top surface and a bottom surface, a first frontside structure disposed above and in contact with the top surface of the substrate, a second frontside structure disposed above and in contact with the top surface of the substrate, and a first insulating layer at least partially enclosing the first frontside structure and the second frontside structure, wherein at least one of the first frontside structure or the second frontside structure comprises a frontside contact, a frontside epitaxial structure, or a frontside gate structure; replacing at least a portion of the substrate with a second insulating layer having a top surface and a bottom surface, the top surface of the second insulating layer being more proximate than the bottom surface of the second insulating layer to the first insulating layer; forming a first BSC and a second BSC, each extending vertically through the second insulating layer, wherein the first BSC electrically connects with the first frontside structure and the second BSC electrically connects with the second frontside structure; and forming a backside resistor structure having a first terminal electrically coupled to the first BSC and a second terminal electrically coupled to the second BSC.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1 and FIG. 2 are cross-sectional views of semiconductor structures with a conventional high-precision resistor.

FIG. 3A, FIG. 3B, and FIG. 3C are cross-sectional views of a high-precision backside resistor, according to aspects of the disclosure.

FIGS. 4A-4F are cross-sections that illustrate steps in a process for fabricating a high-precision backside resistor, according to aspects of the disclosure.

FIGS. 5A-5F are cross-sections that illustrate steps in another process for fabricating a high-precision backside resistor, according to aspects of the disclosure.

FIG. 6 is a flowchart of an example process associated with fabrication of a high-precision backside resistor, according to aspects of the disclosure.

FIG. 7 illustrates a mobile device in accordance with some examples of the disclosure.

FIG. 8 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Integrated circuit (IC) device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device, where the “frontside” traditionally referred to the side having electrical contacts to other devices and the “backside” traditionally referred to the substrate upon which those components were fabricated, and more specifically, to the surface of that substrate opposite the surface upon which the components were fabricated.

As the sizes of the IC devices and the sizes of the components formed thereon become smaller, however, the available area for forming the contacts and interconnects also become smaller. As such, the routing complexity and/or the parasitic resistance and capacitance of the contacts and interconnects may increase and thus the manufacturing cost or the performance of the IC device may be negatively impacted. In response to this problem, backside wafer processes have been created whereby the original substrate upon which the frontside process was performed is thinned (or removed entirely and replaced with an insulating, dielectric, or passivation layer) and contacts and/or vias are etched through the backside to reach frontside components. As process geometries continued to scale, the power distribution network, which was formerly implemented in an upper metal layer, has been migrated to the backside in order to ease frontside routing congestion. These are referred to as backside power distribution networks, or BSPDNs.

“High precision” resistors are typically constructed of a thin layer of material, e.g., titanium nitride (TiN), tantalum nitride (TaN), tungsten silicide (WSi), or tungsten nitride (WN) and have low thermal dependence. High precision resistor structures also became more and more difficult to fabricate as process features were reduced in scale, and so the high precision resistor structures are typically located in higher level frontside interconnect layers created during a back-end-of-line (BEOL) process, rather than created along with active devices during a middle-of-line (MOL) process.

There are disadvantages to this conventional approach, however. For example, the interconnect structures above, below, and beside these resistor structures contribute parasitic resistance and capacitance, which can degrade the precision of the high precision resistor structure. In addition, the thermal effects of the high-precision resistor may necessitate that a specific volume around the resistor-which may also include layers above and/or below the resistor-remain empty of any components and/or wiring, which can further limit how small the IC device can be and may even cancel the intended benefits of process scaling entirely.

To overcome the disadvantages described above, a high precision backside resistor and methods for making the same are herein disclosed. Various aspects relate generally to an integrated circuit device and a manufacturing method of making the integrated circuit device. Some aspects more specifically relate to an integrated circuit device having a high-precision backside resistor structure.

Particular aspects of the subject matter described in this disclosure can be implemented to realize one or more of the following potential advantages: the high-precision backside resistor structures described herein require no change to an existing frontside BEOL process; because backside metal zero (BM0) structures are generally large, process scaling is not an issue for backside resistor structures; backside resistor structures do not pose a thermal concern for backside processes with no signal routing (e.g., with power routing only); and moving the high-precision resistor structure to the backside frees up frontside area and/or routing resources used for frontside BEOL structures.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

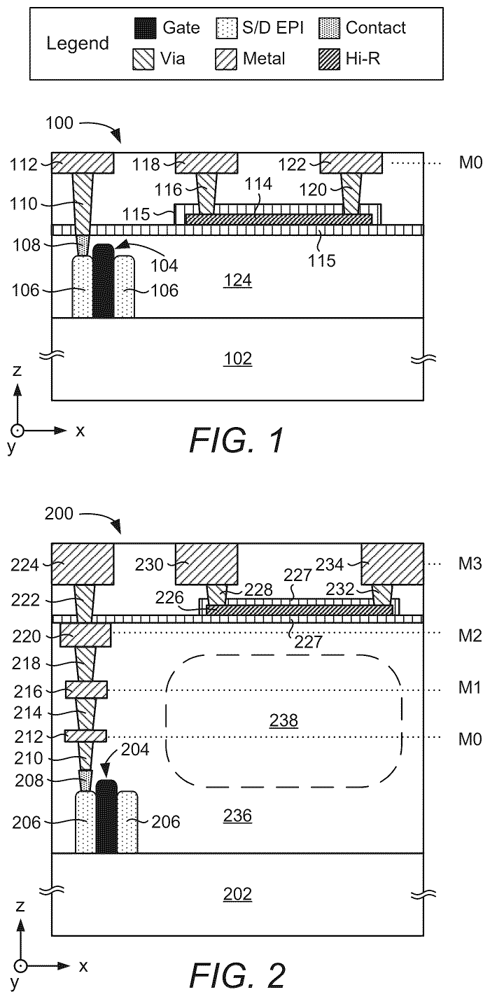

FIG. 1 is a cross-sectional view of a semiconductor structure 100 with a conventional high-precision resistor. In the example shown in FIG. 1, the semiconductor structure 100 includes a substrate 102 upon which has been fabricated a FET comprising a gate structure 104 disposed between two source/drain (S/D) epitaxial (EPI) structures 106. In some aspects, the gate structure 104 may comprise a gate-all-around (GAA) structure with channels (not shown) extending horizontally through the gate structure 104 to connect the two S/D EPI structures 106. As shown in FIG. 1, the semiconductor structure 100 includes an S/D contact 108 and a first level-0 via (V0) 110 to electrically connect a first level-0 metal (M0) structure to one of the S/D EPI structures 106. FIG. 1 illustrates a conventional frontside middle-of-line (MOL) high-precision resistor 114, i.e., fabricated before creation of frontside M0 structures (and thus located below M0 but above devices such as the FET). Fabrication of the high-precision resistor 114 involves the creation of two separate etch stop layers 115, with the associated process steps of deposition, patterning, etch, etc., for each. A second via 116 provides an electrical connection from one terminal of the high-precision resistor 114 to a second M0 structure 118, and a third via 120 provides an electrical connection from another terminal of the high-precision resistor 114 to a third M0 structure 122. The components are embedded within a volume 124 comprising one or more layers of a dielectric, insulating material, passivation material, or a combination thereof.

Although process sizes shrank, however, MOL high-precision resistors are difficult to scale, in part due to the topographic impact on M0 of a small pitch (e.g., <50 nm), so high-precision resistors were fabricated in a BEOL process instead, i.e., placing the resistor above the M0 layer rather than below it. An example of this is shown in FIG. 2.

FIG. 2 is a cross-sectional view of another semiconductor structure 200 with a conventional high-precision resistor. In the example shown in FIG. 2, the semiconductor structure 200 includes a substrate 202 upon which has been fabricated a FET comprising a gate structure 204 disposed between two source/drain (S/D) epitaxial (EPI) structures 206. In some aspects, the gate structure 204 may comprise a gate-all-around (GAA) structure with channels (not shown) extending horizontally through the gate structure 204 to connect the two S/D EPI structures 206. As shown in FIG. 2, the semiconductor structure 200 includes an S/D contact 208 and a V0 210 to electrically connect a first M0 structure 212 to one of the S/D EPI structures 206. In the example shown in FIG. 2, this electrical path continues through a level-1 via (V1) 214, a level-1 metal (M1) structure 216, a level-2 via (V2) 218, a level-2 metal (M2) structure 220, a level-3 via (V3) 222, and a level-3 metal (M3) structure 224. FIG. 2 illustrates a conventional frontside BEOL high-precision resistor 226. Fabrication of the high-precision resistor 226 involves the creation of two separate etch stop layers 227, with the associated process steps of deposition, patterning, etch, etc., for each. A second V3 228 provides an electrical connection from one terminal of the high-precision resistor 226 to a second M3 structure 230, and a third V3 232 provides an electrical connection from another terminal of the high-precision resistor 226 to a third M3 structure 234. The components are embedded within a volume 236 comprising one or more layers of a dielectric, insulating material, passivation material, or a combination thereof.

One disadvantage of the conventional high-precision resistor 226 is that in some aspects, an exclusion zone 238, which is an area or volume in which it is prohibited to place routing structures, is required—e.g., to shield other components from the heat generated by the high-precision resistor 226 or to shield the high-precision resistor 226 from noise that may be caused by nearby signaling traces. Another disadvantage is that the BEOL structure creates additional, unwanted capacitance.

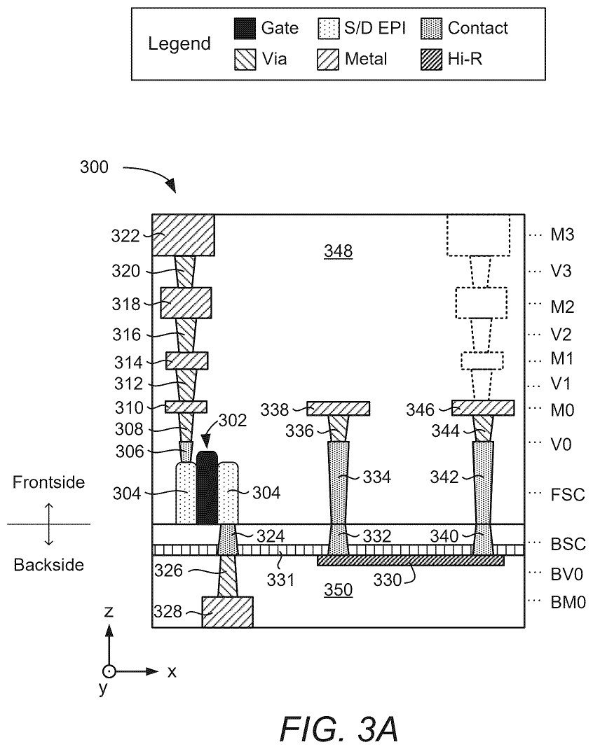

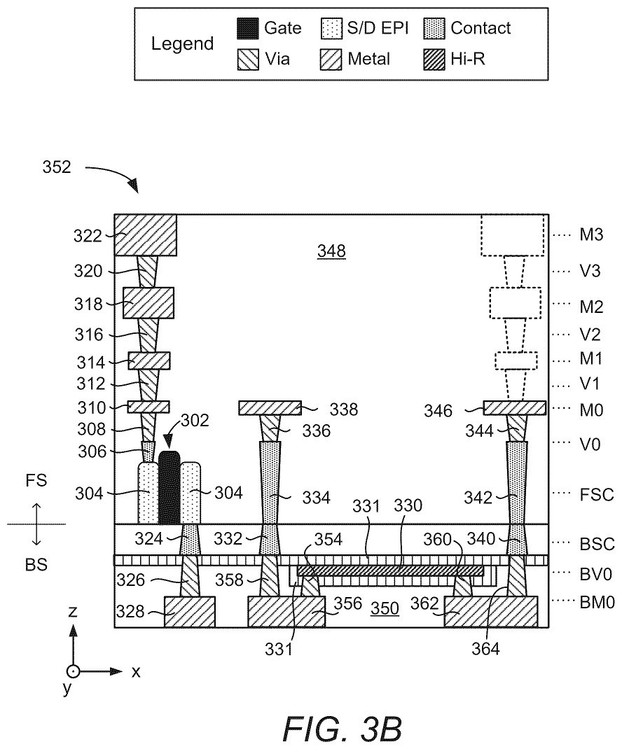

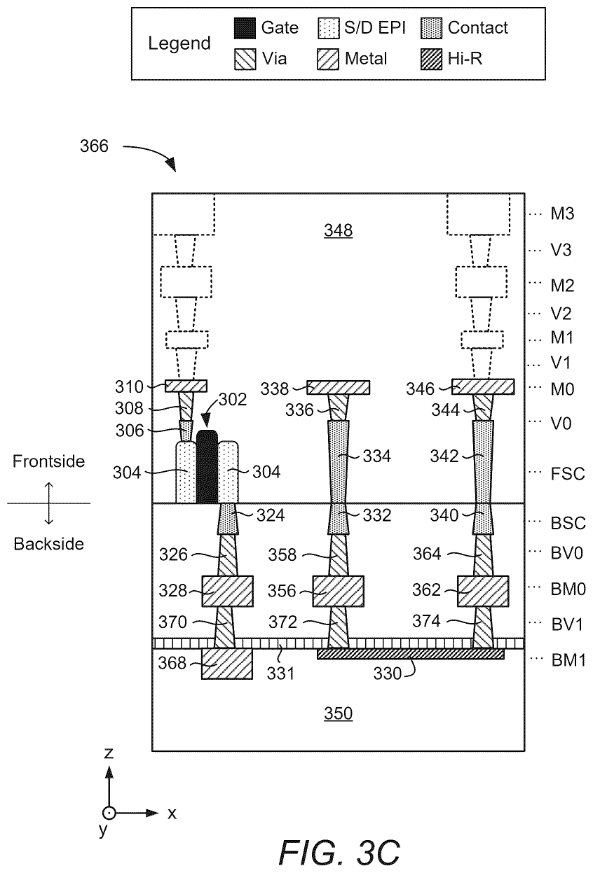

FIG. 3A, FIG. 3B, and FIG. 3C are cross-sectional views of a high-precision backside resistor, according to aspects of the disclosure. The semiconductor structures shown in FIGS. 3A-3B have both frontside structures and backside structures. The frontside structures are fabricated on the frontside of a wafer substrate. The wafer is then flipped over and the substrate is completely or substantially removed, e.g., via a grinding and/or etching process, after which the backside components are fabricated. Thus, the wafer substrate upon which the frontside components were fabricated, and which was later removed, is not shown in FIGS. 3A-3B.

FIG. 3A is a cross-sectional view of a semiconductor structure 300 with a high-precision backside resistor, according to aspects of the disclosure. FIG. 3A merely shows some elements of the semiconductor structure 300 for illustration purposes, and other elements above and/or below the elements shown in FIG. 3A may be omitted from FIG. 3A.

As shown in FIG. 3A, the semiconductor structure 300 includes a FET comprising a gate 302 disposed between two S/D EPI structures 304. In some aspects, the gate 302 may comprise a gate-all-around (GAA) structure with channels (not shown) extending horizontally through the gate 302 to connect the two S/D EPI structures 304. As shown in FIG. 3A, the semiconductor structure 300 includes an S/D contact 306 and a first V0 308 to electrically connect a first M0 310 structure to one of the S/D EPI structures 304. In the example shown in FIG. 3A, this electrical path continues through a V1 312, an M1 structure 314, a V2 316, an M2 structure 318, a V3 320, and an M3 structure 322. As shown in FIG. 3A, the semiconductor structure 300 includes a backside electrical path comprising a first backside contact (BSC) 324 and a backside level-0 via (BV0) that electrically connects the other S/D EPI structure 304 to a backside level-0 metal (BM0) structure 328, which may be part of a backside power distribution network (BSPDN).

As shown in FIG. 3A, the semiconductor structure 300 includes a backside high-precision resistor 330. In the example illustrated in FIG. 3A, the backside high-precision resistor 330 may be fabricated using a backside MOL process and may therefore be referred to as a backside MOL high-precision resistor or similar. In some aspects, fabrication of the backside MOL high-precision resistor 330 may involve the use of an etch stop layer 331. In some aspects, such as when a high selectivity etch is developed (e.g., of TiN versus SiO₂), the etch stop layer 331 may be omitted, since (unlike the case of a high-precision resistor in a FS MOL) there is no concern of impact to a device gate and (unlike the case of a high-precision resistor in a FS BEOL) there is no concern of impact to a copper layer. Electrical connections from the backside high-precision resistor 330 to frontside structures are provided via two electrical paths. A first electrical path includes a second BSC 332, a first frontside contact (FSC) 334, a second V0 336, and a second M0 structure 338. A second electrical path includes a third BSC 340, a second FSC 342, a third V0 344, and a third M0 structure 346. It will be understood that additional structures may be used to extend one or both of the electrical paths to other levels of metal (e.g., M1, M2, M3, etc.), as shown by the optional structures shown with dashed lines in FIG. 3A. As shown in FIG. 3A, the frontside components are embedded within a volume 348 comprising one or more layers of a dielectric, insulating material, passivation material, or a combination thereof, and the backside components are embedded within a volume 350 comprising one or more layers of a dielectric, insulating material, passivation material, or a combination thereof.

FIG. 3B is a cross-sectional view of a semiconductor structure 352 with a high-precision backside resistor, according to aspects of the disclosure. FIG. 3B merely shows some elements of the semiconductor structure 352 for illustration purposes, and other elements above and/or below the elements shown in FIG. 3B may be omitted from FIG. 3B. Numbered elements in FIG. 3B are essentially identical to like-numbered elements in FIG. 3A and therefore their descriptions will not be repeated here. FIG. 3B illustrates an aspect in which the backside high-precision resistor 330 is connected to the frontside structures by way of BM0 structures. In the example shown in FIG. 3B, the backside high-precision resistor 330 does not contact the second BSC 332 and the third BSC 340 directly but though a second BV0 354, a second BM0 structure 356, and a third BV0 358 to the second BSC 332, and through a fourth BV0 360, a third BM0 structure 362, and a fifth BV0 364 to the third BSC 340. It will be understood that additional structures may be used to extend one or both of the electrical paths to or through other levels of backside metal (e.g., BM1, BM2, BM3, etc.) if extant.

FIG. 3C is a cross-sectional view of a semiconductor structure 366 with a high-precision backside resistor, according to aspects of the disclosure. FIG. 3C merely shows some elements of the semiconductor structure 366 for illustration purposes, and other elements above and/or below the elements shown in FIG. 3C may be omitted from FIG. 3C. Numbered elements in FIG. 3C are essentially identical to like-numbered elements in FIG. 3A and FIG. 3B and therefore their descriptions will not be repeated here. FIG. 3C illustrates an aspect in which the backside high-precision resistor 330 is a backside BEOL resistor structure. In the example shown in FIG. 3C, the semiconductor structure 366 has a backside level-one metal (BM1) structure 368 that is electrically connected to the BM0 structure 328 through a backside level-one via (BV1) 370. In the example shown in FIG. 3C, the first terminal of the high-precision resistor 330 is connected to the second BM0 structure 356 through a second BV1 372, and the second terminal of the high-precision resistor 330 is connected to the third BM0 structure 362 through a third BV1 374. Thus, in this example, the high-precision resistor 330 is a backside BEOL resistor structure. It will be understood that, while FIG. 3C illustrates a backside BEOL high-precision resistor that is “below” (in the orientation shown in FIG. 3C) the BM0 layer and connected to the frontside terminals by way of a BM0 structure, in other aspects, the backside BEOL high-precision resistor may be below a BM1 layer and connected to the frontside terminals by way of a BM1 structure, or below a BM2 layer and connected to the frontside terminals by way of a BM2 structure, etc. That is, the high-precision resistor may be located at any BM level of a backside BEOL process.

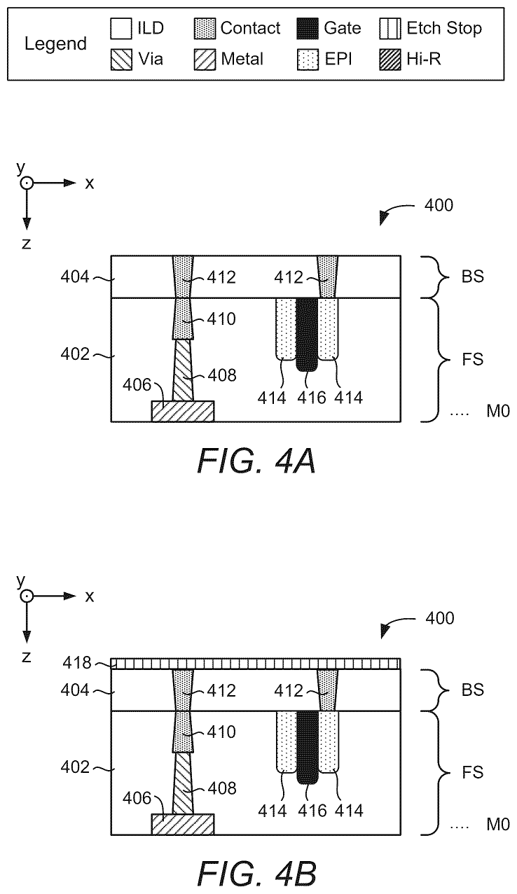

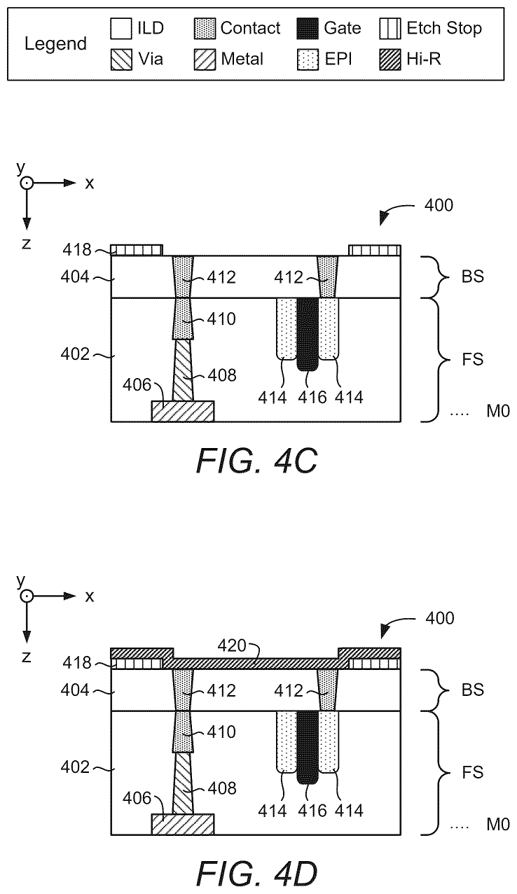

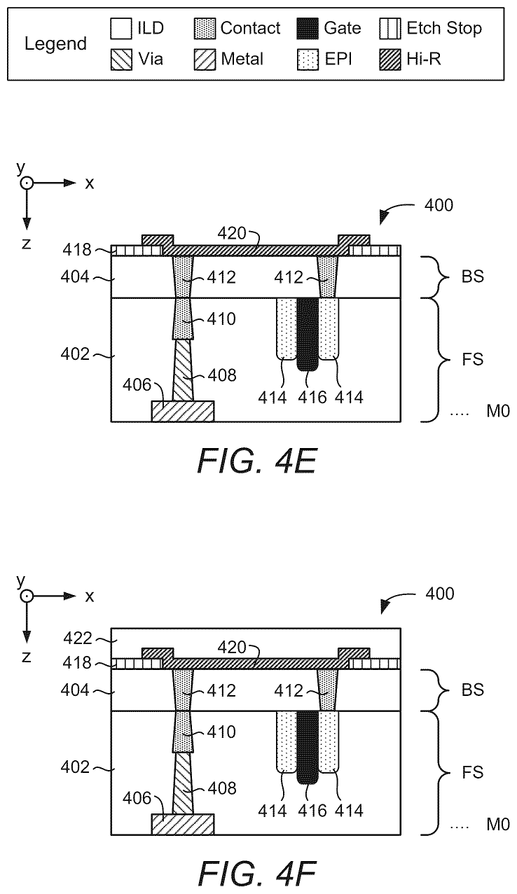

FIGS. 4A-4F are cross-sections that illustrate steps in a process for fabricating a high-precision backside resistor, according to aspects of the disclosure. As shown in FIG. 4A, the process starts with a semiconductor structure 400 comprising frontside process components and backside process components. The frontside process components are embedded within a first volume 402 comprising one or more layers of a dielectric, insulating material, passivation material, or a combination thereof. The backside process components are embedded within a second volume 404 comprising one or more layers of a dielectric, insulating material, passivation material, or a combination thereof. The frontside process components include M0 structures 406, V0 structures 408, and FSCs 410. The backside process components include BSCs 412. In the example illustrated in FIGS. 4A-4F, the frontside components also include a FET comprising source and drain epitaxial structures 414 separated by a gate 416 structure. This example illustrates the point that, in some aspects, a backside resistor structure may be directly coupled to an active device, e.g., without requiring an intervening metallization structure.

FIG. 4A illustrates the result after a BSC formation step. In some aspects, the BSCs 412 comprise tungsten (W). In some aspects, the length of the BSCs 412 has been tailored for later placement of a high-precision backside resistor structure.

FIG. 4B illustrates the result after deposition of an etch stop layer 418. In some aspects, the etch stop layer 418 comprises silicon nitride (SiN) or silicon carbon nitride (SiCN).

FIG. 4C illustrates the result after an etch step that exposes the BSCs 412 that will be the terminal connections to the later-formed high-precision backside resistor.

FIG. 4D illustrates the result after deposition of a resistive material 420 that will form the high-precision backside resistor. In some aspects, the resistive material 420 comprises titanium nitride (TiN), tantalum nitride (TaN), tungsten silicide (WSi), or tungsten nitride (WN).

FIG. 4E illustrates the result after a patterning and etch step that creates the final shape of the high-precision backside resistor.

FIG. 4F illustrates the result after deposition of an insulating material 422. In some aspects, the insulating material 422 comprises silicon dioxide (SiO₂).

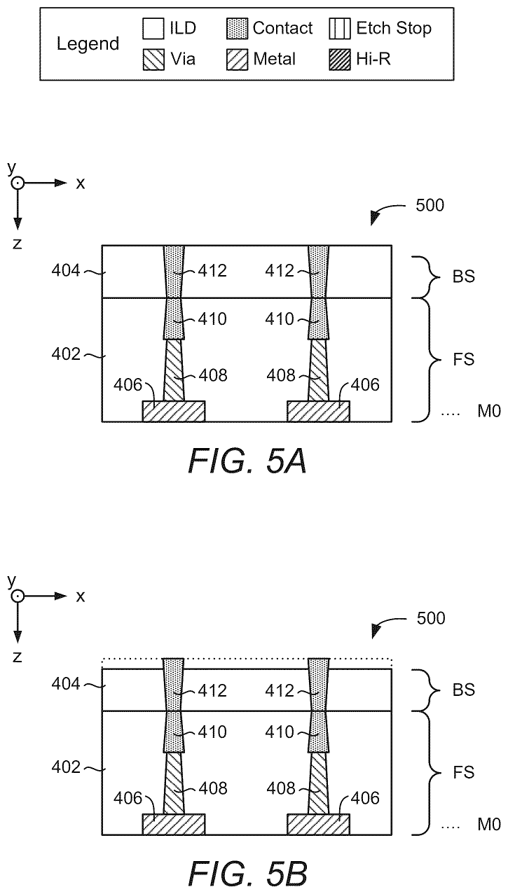

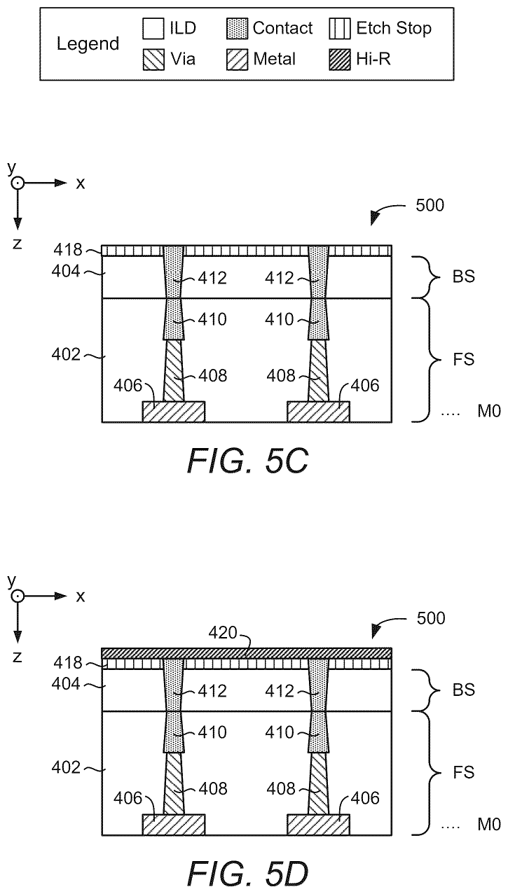

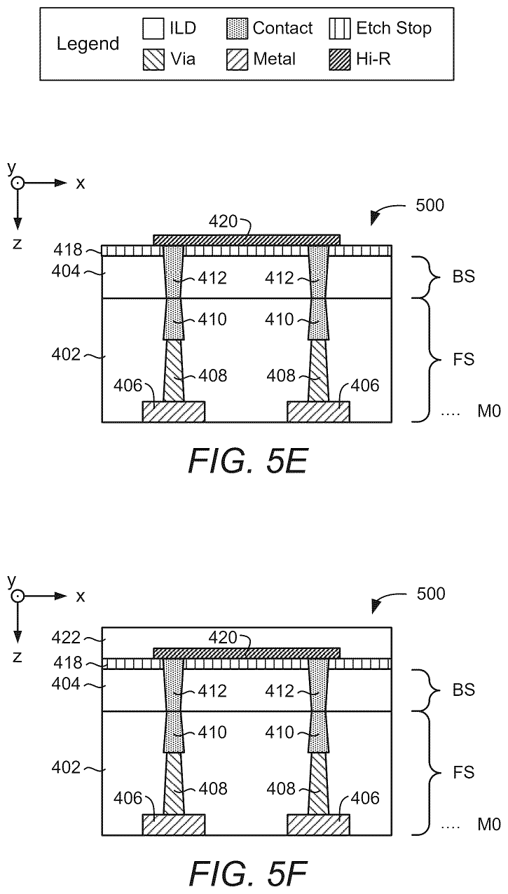

FIGS. 5A-5F are cross-sections that illustrate steps in another process for fabricating a high-precision backside resistor, according to aspects of the disclosure. Numbered elements in FIGS. 5A-5F are essentially identical to like-numbered elements in FIGS. 4A-4Fand therefore their descriptions will not be repeated here. As shown in FIG. 5A, the process starts with a semiconductor structure 500 comprising frontside process components and backside process components. The frontside process components are embedded within a first volume 402 comprising one or more layers of a dielectric, insulating material, passivation material, or a combination thereof. The backside process components are embedded within a second volume 404 comprising one or more layers of a dielectric, insulating material, passivation material, or a combination thereof. The frontside process components include M0 structures 406, V0 structures 408, and FSCs 410. The backside process components include BSCs 412.

FIG. 5A illustrates the result after a BSC formation step. In some aspects, the BSCs 412 comprise tungsten (W). In some aspects, the length of the BSCs 412 has been tailored for later placement of a high-precision backside resistor structure.

FIG. 5B illustrates the result after an etch step that removes a portion of the second volume 404 to expose the BSCs 412 that will be the terminal connections to the later-formed high-precision backside resistor.

FIG. 5C illustrates the result after deposition of a an etch stop layer 418 and a chemical mechanical polishing (CMP) step that exposes the tops of the BSCs 412. In some aspects, the etch stop layer 418 comprises silicon nitride (SiN) or silicon carbon nitride (SiCN).

FIG. 5D illustrates the result after deposition of a resistive material 420 that will form the high-precision backside resistor. In some aspects, the resistive material comprises titanium nitride (TiN), tantalum nitride (TaN), tungsten silicide (WSi), or tungsten nitride (WN).

FIG. 5E illustrates the result after a patterning and etch step that creates the final shape of the high-precision backside resistor.

FIG. 5F illustrates the result after deposition of an insulating material 422. In some aspects, the insulating material 422 comprises silicon dioxide (SiO₂).

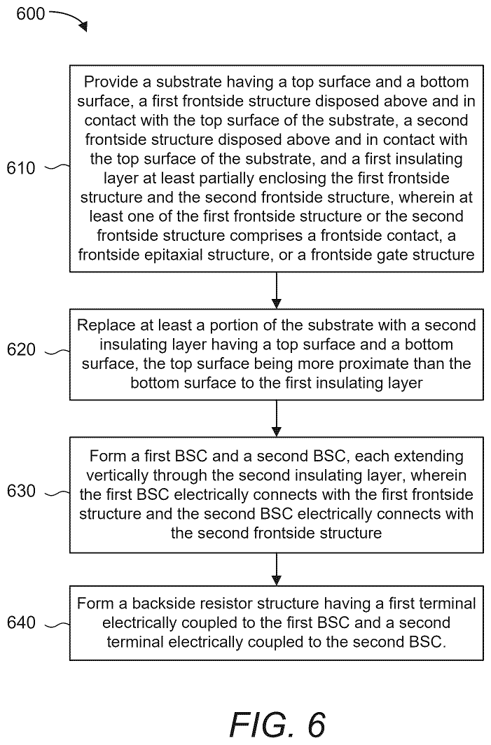

FIG. 6 is a flowchart of an example process 600 associated with high-precision backside resistors, according to aspects of the disclosure. As shown in FIG. 6, process 600 may include, at block 610, providing a substrate having a top surface and a bottom surface, a first frontside structure disposed above and in contact with the top surface of the substrate, a second frontside structure disposed above and in contact with the top surface of the substrate, and a first insulating layer at least partially enclosing the first frontside structure and the second frontside structure, wherein at least one of the first frontside structure or the second frontside structure comprises a frontside contact, a frontside epitaxial structure, or a frontside gate structure. An example of the result of block 610 can be seen in FIG. 4A as the volume 402, which includes a first insulating layer and the frontside structures enclosed within, and having a first frontside structure, FSC 410, and a second frontside structure, epitaxial structure 414.

As further shown in FIG. 6, process 600 may include, at block 620, replacing at least a portion of the substrate with a second insulating layer having a top surface and a bottom surface, the top surface of the second insulating layer being more proximate than the bottom surface of the second insulating layer to the first insulating layer. An example of the result of block 620 can be seen in FIG. 4A as the volume 404, which includes a second insulating layer.

As further shown in FIG. 6, process 600 may include, at block 630, forming a first backside contact (BSC) and a second BSC, each extending vertically through the second insulating layer, wherein the first BSC electrically connects with the first frontside structure and the second BSC electrically connects with the second frontside structure. An example of the result of block 630 can be seen in FIG. 4A as the BSCs 412 within the volume 404.

As further shown in FIG. 6, process 600 may include, at block 640, forming a backside resistor structure having a first terminal electrically coupled to the first BSC and a second terminal electrically coupled to the second BSC. An example of the result of block 640 can be seen in FIG. 4F as the backside resistor structure 420.

In some aspects, forming the backside resistor structure having the first terminal electrically coupled to the first BSC and the second terminal electrically coupled to the second BSC comprises depositing an etch stop material on the bottom surface of the second insulating layer and covering the first BSC and the second BSC, etching the etch stop material to expose the first BSC and the second BSC, depositing a resistive layer that makes electrical contact with the first BSC and the second BSC, etching the resistive layer to form the backside resistor structure having the first terminal that is connected to the first BSC and the second terminal that is connected to the second BSC, and depositing an interlayer dielectric (ILD) layer over the backside resistive structure. An example result of these process steps can be seen in FIG. 4B through FIG. 4F.

In some aspects, forming the backside resistor structure having the first terminal electrically coupled to the first BSC and the second terminal electrically coupled to the second BSC comprises removing a portion of the second insulating layer to expose the first BSC and he second BSC, depositing an etch stop material over the bottom surface of the second insulating layer and the first BSC and the second BSC, performing a chemical mechanical polishing (CMP) process to expose the first BSC and the second BSC, depositing a resistive layer that makes electrical contact with the first BSC and the second BSC, etching the resistive layer to form the backside resistor structure having the first terminal that is connected to the first BSC and the second terminal that is connected to the second BSC, and depositing an interlayer dielectric (ILD) layer to cover the backside resistor structure. An example result of these process steps can be seen in FIG. 5B through FIG. 5F.

In some aspects, forming the backside resistor structure having the first terminal electrically coupled to the first BSC and the second terminal electrically coupled to the second BSC comprises depositing, onto the bottom surface of the second insulating layer, a resistive layer, etching the resistive layer to form the backside resistor structure having the first terminal and the second terminal, depositing a third insulating layer onto at least a bottom surface of the backside resistor structure, forming a first backside via (BSV), a second BSV, a third BSV, and a fourth BSV, each extending vertically through the third insulating layer, wherein the first BSV electrically connects with the first terminal of the backside resistor structure, the second BSV electrically connects with the second terminal of the backside resistor structure, the third BSV electrically connects to the first BSC, and the fourth BSV electrically connects to the second BSC, and forming a first backside level-0 metal (BM0) structure and a second BM0 structure, wherein the first BM0 structure electrically connects the first BSV and the third BSV and wherein the second BM0 structure electrically connects the second BSV and the fourth BSV.

In some aspects, forming the first BSV, the second BSV, the third BSV, and the fourth BSV comprises depositing tungsten (W).

In some aspects, forming the backside resistor structure comprises forming a high-precision resistor.

In some aspects, forming the backside resistor structure comprises forming the backside resistor structure comprising titanium nitride (TiN), tantalum nitride (TaN), tungsten silicide (WSi), or tungsten nitride (WN).

In some aspects, forming the backside resistor structure comprises depositing an etch stop layer.

Process 600 may include additional implementations, such as any single implementation or any combination of implementations described below and/or in connection with one or more other processes described elsewhere herein. Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

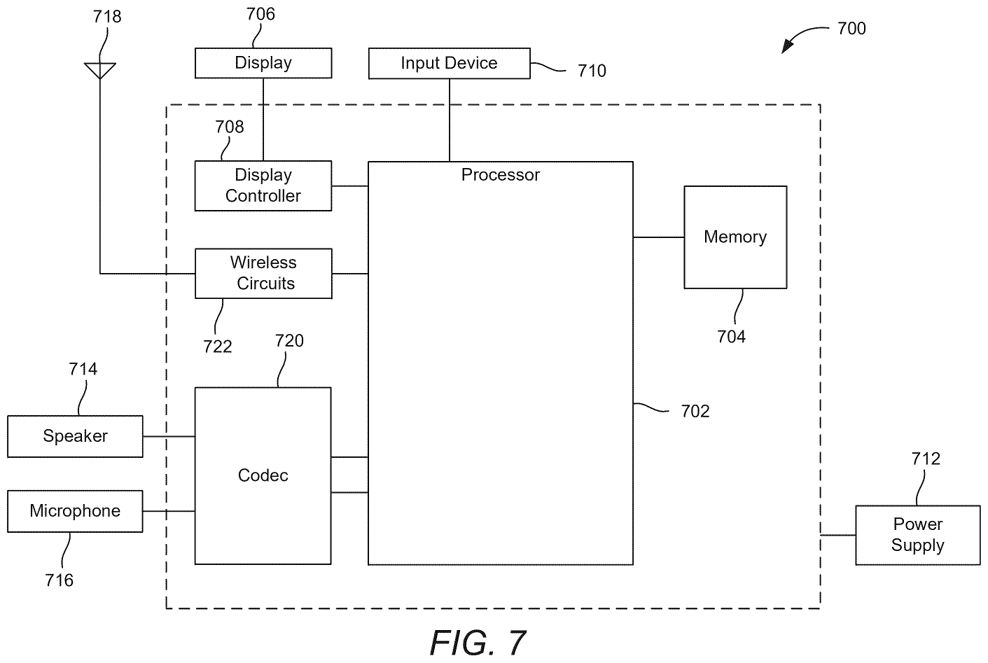

FIG. 7 illustrates a mobile device 700, according to aspects of the disclosure. In some aspects, the mobile device 700 may be implemented by including one or more IC devices manufactured based on the examples described in this disclosure.

In some aspects, mobile device 700 may be configured as a wireless communication device. As shown, mobile device 700 includes processor 702. Processor 702 may be communicatively coupled to memory 704 over a link, which may be a die-to-die or chip-to-chip link. Mobile device 700 also includes display 706 and display controller 708, with display controller 708 coupled to processor 702 and to display 706. The mobile device 700 may include input device 710 (e.g., physical, or virtual keyboard), power supply 712 (e.g., battery), speaker 714, microphone 716, and wireless antenna 718. In some aspects, the power supply 712 may directly or indirectly provide the supply voltage for operating some or all of the components of the mobile device 700.

In some aspects, FIG. 7 may include coder/decoder (CODEC) 720 (e.g., an audio and/or voice CODEC) coupled to processor 702; speaker 714 and microphone 716 coupled to CODEC 720; and wireless circuits 722 (which may include a modem, RF circuitry, filters, etc.) coupled to wireless antenna 718 and to processor 702.

In some aspects, one or more of processor 702, display controller 708, memory 704, CODEC 720, and wireless circuits 722 may include one or more IC devices including semiconductor structures manufactured according to the examples described in this disclosure.

It should be noted that although FIG. 7 depicts a mobile device 700, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

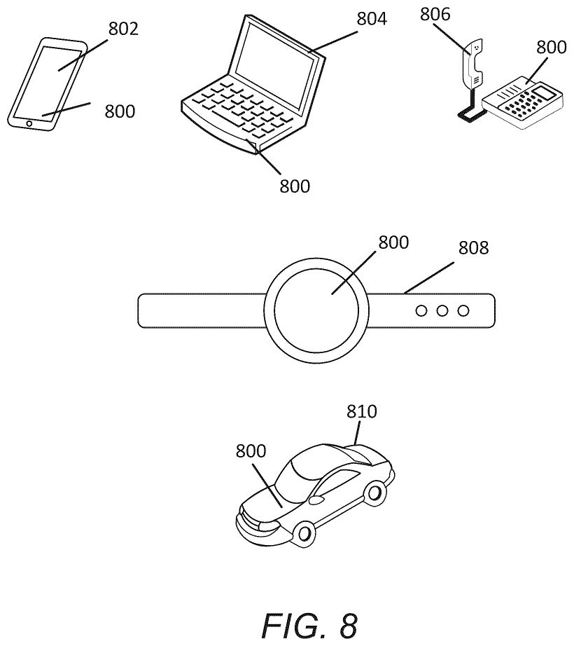

FIG. 8 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 802, a laptop computer device 804, a fixed location terminal device 806, a wearable device 808, or automotive vehicle 810 may include a semiconductor device 800 (e.g., semiconductor structures 300, 352, 400, and 500) as described herein. The devices 802, 804, 806 and 808 and the vehicle 810 illustrated in FIG. 8 are merely exemplary. Other apparatuses or devices may also feature the semiconductor device 800 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A semiconductor apparatus, comprising: a backside resistor structure having a first terminal and a second terminal and being disposed between a frontside level-zero metal (FM0) layer and a backside level-zero metal (BM0) layer, wherein the first terminal is electrically coupled to a first frontside structure through a first conductive path comprising at least a first backside contact (BSC), wherein the second terminal is electrically coupled to a second frontside structure through a second conductive path comprising at least a second BSC, and wherein at least one of the first frontside structure or the second frontside structure comprises a frontside contact, a frontside epitaxial structure, or a frontside gate structure.

Clause 2. The semiconductor apparatus of clause 1, wherein the backside resistor structure comprises titanium nitride (TiN), tantalum nitride (TaN), tungsten silicide (WSi), or tungsten nitride (WN).

Clause 3. The semiconductor apparatus of any of clauses 1 to 2, wherein the backside resistor structure comprises a backside middle-of-line (MOL) structure.

Clause 4. The semiconductor apparatus of any of clauses 1 to 3, wherein each of the first FSV and the second FSV comprises a frontside middle-of-line (MOL) via.

Clause 5. The semiconductor apparatus of any of clauses 1 to 4, wherein: the first BSC is in contact with the first terminal, and the second BSC in in contact with the second terminal.

Clause 6. The semiconductor apparatus of any of clauses 1 to 5, wherein: the first BSC is in contact with a first backside via (BSV), the first BSV is in contact with a first backside M0 (BM0) structure, the first BM0 structure is in contact with a second BSV, and the second BSV is in contact with the first terminal, and the second BSC is in contact with a third BSV, the third BSV is in contact with a second BM0 structure, the second BM0 structure is in contact with a fourth BSV, and the fourth BSV is in contact with the second terminal.

Clause 7. The semiconductor apparatus of clause 6, wherein each of the first BSV, the second BSV, the third BSV, and the fourth BSV comprises a backside middle-of-line (MOL) via.

Clause 8. A semiconductor apparatus, comprising: a backside resistor structure having a first terminal and a second terminal and being disposed between a first backside metal layer and a second backside metal layer, wherein the first terminal is electrically coupled to a first frontside structure through a first conductive path comprising at least a first backside contact (BSC), first backside level-zero via (BSV0), a first backside level-zero metal (BM0) structure, and a first backside level-one via (BSV1), wherein the second terminal is electrically coupled to a second frontside structure through a second conductive path comprising at least a second BSC, a second BSV0, a second BM0 structure, and a second BSV1, and wherein at least one of the first frontside structure or the second frontside structure comprises a frontside contact, a frontside epitaxial structure, or a frontside gate structure.

Clause 9. The semiconductor apparatus of clause 8, wherein the backside resistor structure comprises titanium nitride (TiN), tantalum nitride (TaN), tungsten silicide (WSi), or tungsten nitride (WN).

Clause 10. The semiconductor apparatus of any of clauses 8 to 9, wherein the backside resistor structure comprises a backside back-end-of-line (BEOL) structure.

Clause 11. A method for fabricating a semiconductor apparatus, the method comprising: providing a substrate having a top surface and a bottom surface, a first frontside structure disposed above and in contact with the top surface of the substrate, a second frontside structure disposed above and in contact with the top surface of the substrate, and a first insulating layer at least partially enclosing the first frontside structure and the second frontside structure, wherein at least one of the first frontside structure or the second frontside structure comprises a frontside contact, a frontside epitaxial structure, or a frontside gate structure; replacing at least a portion of the substrate with a second insulating layer having a top surface and a bottom surface, the top surface of the second insulating layer being more proximate than the bottom surface of the second insulating layer to the first insulating layer; forming a first backside contact (BSC) and a second BSC, each extending vertically through the second insulating layer, wherein the first BSC electrically connects with the first frontside structure and the second BSC electrically connects with the second frontside structure; and forming a backside resistor structure having a first terminal electrically coupled to the first BSC and a second terminal electrically coupled to the second BSC.

Clause 12. The method of clause 11, wherein forming the backside resistor structure having the first terminal electrically coupled to the first BSC and the second terminal electrically coupled to the second BSC comprises: depositing an etch stop material on the bottom surface of the third insulating layer and covering the first BSC and the second BSC; etching the etch stop material to expose the first BSC and the second BSC; depositing a resistive layer that makes electrical contact with the first BSC and the second BSC; etching the resistive layer to form the backside resistor structure having the first terminal that is connected to the first BSC and the second terminal that is connected to the second BSC; and depositing an interlayer dielectric (ILD) layer over the backside resistive structure.

Clause 13. The method of any of clauses 11 to 12, wherein forming the backside resistor structure having the first terminal electrically coupled to the first BSC and the second terminal electrically coupled to the second BSC comprises: removing a portion of the third insulating layer to expose the first BSC and he second BSC; depositing an etch stop material over the bottom surface of the third insulating layer and the first BSC and the second BSC; performing a chemical mechanical polishing (CMP) process to expose the first BSC and the second BSC; depositing a resistive layer that makes electrical contact with the first BSC and the second BSC; etching the resistive layer to form the backside resistor structure having the first terminal that is connected to the first BSC and the second terminal that is connected to the second BSC; and depositing an interlayer dielectric (ILD) layer to cover the backside resistor structure.

Clause 14. The method of any of clauses 11 to 13, wherein forming the backside resistor structure having the first terminal electrically coupled to the first BSC and the second terminal electrically coupled to the second BSC comprises: depositing, onto the bottom surface of the third insulating layer, a resistive layer; etching the resistive layer to form the backside resistor structure having the first terminal and the second terminal; depositing a third insulating layer onto at least a bottom surface of the backside resistor structure; forming a first backside via (BSV), a second BSV, a third BSV, and a fourth BSV, each extending vertically through the third insulating layer, wherein the first BSV electrically connects with the first terminal of the backside resistor structure, the second BSV electrically connects with the second terminal of the backside resistor structure, the third BSV electrically connects to the first BSC, and the fourth BSV electrically connects to the second BSC; and forming a first backside level-0 metal (BM0) structure and a second BM0 structure, wherein the first BM0 structure electrically connects the first BSV and the third BSV and wherein the second BM0 structure electrically connects the second BSV and the fourth BSV.

Clause 15. The method of clause 14, wherein forming the first BSV, the second BSV, the third BSV, and the fourth BSV comprises depositing tungsten (W).

Clause 16. The method of any of clauses 11 to 15, wherein forming the backside resistor structure comprises forming a high-precision resistor.

Clause 17. The method of any of clauses 11 to 16, wherein forming the backside resistor structure comprises forming the backside resistor structure comprises titanium nitride (TiN), tantalum nitride (TaN), tungsten silicide (WSi), or tungsten nitride (WN).

Clause 18. The method of any of clauses 11 to 17, wherein forming the backside resistor structure comprises depositing an etch stop layer.

Clause 19. The method of any of clauses 11 to 18, wherein forming the backside resistor structure comprises forming a backside middle-of-line resistor structure.

Clause 20. The method of any of clauses 11 to 19, wherein forming the backside resistor structure comprises forming a backside back-end-of-line resistor structure.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor apparatus, comprising:
a backside resistor structure having a first terminal and a second terminal and being disposed between a frontside level-zero metal (FM0) layer and a backside level-zero metal (BM0) layer,
wherein the first terminal is electrically coupled to a first frontside structure through a first conductive path comprising at least a first backside contact (BSC),
wherein the second terminal is electrically coupled to a second frontside structure through a second conductive path comprising at least a second BSC, and
wherein at least one of the first frontside structure or the second frontside structure comprises a frontside contact, a frontside epitaxial structure, or a frontside gate structure.

2. The semiconductor apparatus of claim 1, wherein the backside resistor structure comprises titanium nitride (TiN), tantalum nitride (TaN), tungsten silicide (WSi), or tungsten nitride (WN).

3. The semiconductor apparatus of claim 1, wherein the backside resistor structure comprises a backside middle-of-line (MOL) structure.

4. The semiconductor apparatus of claim 1, wherein at least one of the first conductive path and the second conductive path comprises a frontside middle-of-line (MOL) via.

5. The semiconductor apparatus of claim 1, wherein:
the first BSC is in contact with the first terminal, and
the second BSC in in contact with the second terminal.

6. The semiconductor apparatus of claim 1, wherein:
the first BSC is in contact with a first backside via (BSV), the first BSV is in contact with a first backside M0 (BM0) structure, the first BM0 structure is in contact with a second BSV, and the second BSV is in contact with the first terminal, and
the second BSC is in contact with a third BSV, the third BSV is in contact with a second BM0 structure, the second BM0 structure is in contact with a fourth BSV, and the fourth BSV is in contact with the second terminal.

7. The semiconductor apparatus of claim 6, wherein each of the first BSV, the second BSV, the third BSV, and the fourth BSV comprises a backside middle-of-line (MOL) via.

8. A semiconductor apparatus, comprising:
a backside resistor structure having a first terminal and a second terminal and being disposed between a first backside metal layer and a second backside metal layer,
wherein the first terminal is electrically coupled to a first frontside structure through a first conductive path comprising at least a first backside contact (BSC), first backside level-zero via (BSV0), a first backside level-zero metal (BM0) structure, and a first backside level-one via (BSV1),
wherein the second terminal is electrically coupled to a second frontside structure through a second conductive path comprising at least a second BSC, a second BSV0, a second BM0 structure, and a second BSV1, and
wherein at least one of the first frontside structure or the second frontside structure comprises a frontside contact, a frontside epitaxial structure, or a frontside gate structure.

9. The semiconductor apparatus of claim 8, wherein the backside resistor structure comprises titanium nitride (TiN), tantalum nitride (TaN), tungsten silicide (WSi), or tungsten nitride (WN).

10. The semiconductor apparatus of claim 8, wherein the backside resistor structure comprises a backside back-end-of-line (BEOL) structure.

11. A method for fabricating a semiconductor apparatus, the method comprising:
providing a substrate having a top surface and a bottom surface, a first frontside structure disposed above and in contact with the top surface of the substrate, a second frontside structure disposed above and in contact with the top surface of the substrate, and a first insulating layer at least partially enclosing the first frontside structure and the second frontside structure, wherein at least one of the first frontside structure or the second frontside structure comprises a frontside contact, a frontside epitaxial structure, or a frontside gate structure;
replacing at least a portion of the substrate with a second insulating layer having a top surface and a bottom surface, the top surface of the second insulating layer being more proximate than the bottom surface of the second insulating layer to the first insulating layer;
forming a first backside contact (BSC) and a second BSC, each extending vertically through the second insulating layer, wherein the first BSC electrically connects with the first frontside structure and the second BSC electrically connects with the second frontside structure; and
forming a backside resistor structure having a first terminal electrically coupled to the first BSC and a second terminal electrically coupled to the second BSC.

12. The method of claim 11, wherein forming the backside resistor structure having the first terminal electrically coupled to the first BSC and the second terminal electrically coupled to the second BSC comprises:
depositing an etch stop material on the bottom surface of the second insulating layer and covering the first BSC and the second BSC;
etching the etch stop material to expose the first BSC and the second BSC;
depositing a resistive layer that makes electrical contact with the first BSC and the second BSC;
etching the resistive layer to form the backside resistor structure having the first terminal that is connected to the first BSC and the second terminal that is connected to the second BSC; and
depositing an interlayer dielectric (ILD) layer over the backside resistive structure.

13. The method of claim 11, wherein forming the backside resistor structure having the first terminal electrically coupled to the first BSC and the second terminal electrically coupled to the second BSC comprises:
removing a portion of the second insulating layer to expose the first BSC and he second BSC;
depositing an etch stop material over the bottom surface of the second insulating layer and the first BSC and the second BSC;
performing a chemical mechanical polishing (CMP) process to expose the first BSC and the second BSC;
depositing a resistive layer that makes electrical contact with the first BSC and the second BSC;
etching the resistive layer to form the backside resistor structure having the first terminal that is connected to the first BSC and the second terminal that is connected to the second BSC; and
depositing an interlayer dielectric (ILD) layer to cover the backside resistor structure.

14. The method of claim 11, wherein forming the backside resistor structure having the first terminal electrically coupled to the first BSC and the second terminal electrically coupled to the second BSC comprises:
depositing, onto the bottom surface of the second insulating layer, a resistive layer;
etching the resistive layer to form the backside resistor structure having the first terminal and the second terminal;
depositing a third insulating layer onto at least a bottom surface of the backside resistor structure;
forming a first backside via (BSV), a second BSV, a third BSV, and a fourth BSV, each extending vertically through the third insulating layer, wherein the first BSV electrically connects with the first terminal of the backside resistor structure, the second BSV electrically connects with the second terminal of the backside resistor structure, the third BSV electrically connects to the first BSC, and the fourth BSV electrically connects to the second BSC; and
forming a first backside level-0 metal (BM0) structure and a second BM0 structure, wherein the first BM0 structure electrically connects the first BSV and the third BSV and wherein the second BM0 structure electrically connects the second BSV and the fourth BSV.

15. The method of claim 14, wherein forming the first BSV, the second BSV, the third BSV, and the fourth BSV comprises depositing tungsten (W).

16. The method of claim 11, wherein forming the backside resistor structure comprises forming a high-precision resistor.

17. The method of claim 11, wherein forming the backside resistor structure comprises forming the backside resistor structure comprises titanium nitride (TiN), tantalum nitride (TaN), tungsten silicide (WSi), or tungsten nitride (WN).

18. The method of claim 11, wherein forming the backside resistor structure comprises depositing an etch stop layer.

19. The method of claim 11, wherein forming the backside resistor structure comprises forming a backside middle-of-line resistor structure.

20. The method of claim 11, wherein forming the backside resistor structure comprises forming a backside back-end-of-line resistor structure.
